(19) United States
(12) Patent Application Publication
(10) Pub. No.: US 2024/0086597 A1
(43) Pub. Date: Mar. 14, 2024

(54) GENERATION AND UTILIZATION OF VIRTUAL FEATURES FOR PROCESS MODELING

(71) Applicant: Applied Materials, Inc., Santa Clara, CA (US)

(72) Inventors: Sundar Narayanan, Cupertino, CA (US); Samit Barai, Chennai (IN); Nusrat Jahan Chhanda, Milpitas, CA (US); Dheeraj Kumar, San Jose, CA (US); Pardeep Kumar, Greater Noida (IN); Anantha R. Sethuraman, Palo Alto, CA (US); Raman Krishnan Nurani, Channai (IN)

(21) Appl. No.: 18/244,787

(22) Filed: Sep. 11, 2023

(30) Foreign Application Priority Data
Sep. 14, 2022 (IN) 202241052560

(51) Int. Cl. G06F 30/27

(52) U.S. Cl. CPC G06F 30/27

(57) ABSTRACT

A method includes receiving profile data of a plurality of features of a substrate. The method further includes generating a typical profile based on the profile data of the plurality of features. The method further includes generating a first array of features. Each of the first array of features is based on the typical profile. The method further includes providing the first array of features to a process model. The method further includes obtaining first output from the process model based on the first array of features. The method further includes causing performance of a corrective action in view of the first output from the process model.

### RELATED APPLICATIONS

This application claims the benefit under 35 U.S.C. § 119(a) of Indian Patent Application No. 202241052560, filed Sep. 14, 2022, which is incorporated by reference herein.

### TECHNICAL FIELD

The present disclosure relates to methods associated with process models used for assessment of manufactured devices, such as semiconductor devices. More particularly, the present disclosure relates to methods for generating and utilizing virtual features for process modeling.

### BACKGROUND

Products may be produced by performing one or more manufacturing processes using manufacturing equipment. For example, semiconductor manufacturing equipment may be used to produce substrates via semiconductor manufacturing processes. Products are to be produced with particular properties, suited for a target application. Properties of an input substrate to a process operation has an effect on output of that process operation. Process models may be utilized to predict outcomes of process operations.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular embodiments of the disclosure or any scope of the claims. Its sole purpose is to present some concepts of the disclosure in a simplified form as a prelude to the more detailed description that is presented later.

In one aspect of the present disclosure, a method includes receiving profile data of a plurality of features of a substrate. The method further includes generating a typical profile based on the profile data of the plurality of features. The method further includes generating a first array of features. Each of the first array of features is based on the typical profile. The method further includes providing the first array of features to a process model. The method further includes obtaining first output from the process model based on the first array of features. The method further includes causing performance of a corrective action in view of the first output from the process model.

In another aspect of the disclosure, a system includes memory and a processing device coupled to the memory. The processing device is to perform operations. The operations include receiving profile data of a plurality of features of a substrate. The operations further include generating a typical profile based on the profile data of the plurality of features. The operations further include generating a first array of features. Each of the first array of features is based on the typical profile. The operations further include providing the first array of features to a process model. The operations further include obtaining first output from the process model based on the first array of features. The operations further include causing performance of a corrective action in view of the first output from the process model.

In another aspect of the disclosure, a non-transitory machine-readable storage medium stores instructions. When executed, the instructions cause a processing device to perform operations. The operations include receiving profile data of a plurality of features of a substrate. The operations further include generating a typical profile based on the profile data of the plurality of features. The operations further include generating a first array of features. Each of the first array of features is based on the typical profile. The operations further include providing the first array of features to a process model. The operations further include obtaining first output from the process model based on the first array of features. The operations further include causing performance of a corrective action in view of the first output from the process model.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to some embodiments.

FIG. 2A depicts a block diagram of an example data set generator for creating data sets for one or more supervised models, according to some embodiments.

FIG. 2B depicts a block diagram of an example data set generator for creating data sets for one or more unsupervised models, according to some embodiments.

FIG. 3 is a block diagram illustrating a system for generating output data, according to some embodiments.

FIG. 4A is a flow diagram of a method for generating a data set for a machine learning model, according to some embodiments.

FIG. 4B is a flow diagram of a method for utilizing measurements of features of a substrate for performing a corrective action, according to some embodiments.

FIG. 4C is a flow diagram of a method for generating and utilizing parameterization of a feature, according to some embodiments.

FIG. 4D is a flow diagram of a method for obtaining predictive output from a process model, according to some embodiments.

FIG. 5 depicts an example substrate including features, according to some embodiments.

FIG. 6 is a block diagram illustrating a computer system, according to some embodiments.

### DETAILED DESCRIPTION

Described herein are technologies related to modeling operations of processing procedures utilizing an applicable range of input features. Manufacturing equipment is used to produce products, such as substrates (e.g., wafers, semiconductors). Manufacturing equipment may include a manufacturing or processing chamber to separate the substrate from the environment. The properties of produced substrates are to meet target values to facilitate specific functionalities. Manufacturing parameters are selected to produce substrates that meet the target property values. Many manufacturing parameters (e.g., hardware parameters, process parameters, etc.) contribute to the properties of processed substrates. Manufacturing systems may control parameters by specifying a set point for a property value, receiving data from sensors disposed within the manufacturing chamber, and making adjustments to the manufacturing equipment until the sensor readings match the set point.

A processing procedure (e.g., a method of manufacturing a substrate) may include many processing operations (e.g., processing steps). For example, a semiconductor wafer may be manufactured by adding material to a substrate in one or more deposition operations, removing material from the substrate in one or more etch operations, altering properties of the substrate in one or more annealing operations, etc. Deposition operations, for example, may deposit material on a surface of the substrate, in a hole of a substrate, on a sidewall of a feature or structure of a substrate, etc. Output of a processing operation is dependent on the input product the operation is performed upon. For example, results of a deposition operation depend on the properties of the substrate upon which material is deposited.

It may be valuable to predict results of a processing operation. Results may be predicted via modeling, e.g., using one or more physics-based models to predict the outcome of a processing operation. A physics-based model may include a deposition model, an etch model, and/or a model for any type of processing performed upon a substrate. A model may be provided with data indicative of an input substrate, and generate a prediction of an output substrate after performance of the modeled processing operation. Substrate process models include simulation models, which receive as input simulation parameters such as etch or deposition rate, change in etch or deposition rate over time, etc. Substrate process models may include models that receive as input process parameters, such as gas flow rate, temperature, radio frequency (RF) parameters, etc.

In some conventional systems, properties of a substrate input to a processing operation may be modeled. Performing the modeling may be an expensive process, in terms of time, processing power, subject matter expertise, etc. In some systems, multiple processing operations may be performed sequentially. Results of each operation may impact the next. A modeling approach may take into account each of many processing operations, further compounding the time and cost investment for accurate modeling results.

In some conventional systems, properties of a substrate input to a processing operation may be measured, and a model generated from the measurements. A substrate may include multiple features, such as pillars, gates, trenches, holes, or the like. Multiple features may be nominally or ideally identical. For example, a substrate processing procedure may target generating a substrate with a 2-dimensional or 3-dimensional array of identical features. Differences between features may arise due to non-homogeneity within the process chamber, differences between features of an input structure to a processing operation, differences in measurement of the features, etc. Applying a process model (e.g., a deposition model) may generate results which are impacted by the differences between features of the substrate. Results of the process model may not generate a clear picture of the impact that input feature structure has on output features. Results of the process model may not generate results with clear indication of changes or improvements to be made to input structures to generate target output structures. Results of the process model may be restricted to shapes, characteristics, and parameters of features present in the substrate measured to provide input to the process model.

In some conventional systems, input features of multiple substrates may be measured and provided to a process model. A range of substrates may provide more data for input/output mapping than modeling based on few substrates, a wider range of input features for greater coverage of input and output space, etc. Providing many substrates for measurement may be costly in terms of material, energy, time, equipment wear, maintenance, cost of disposal of products, cost of metrology, etc. Generating a greater range of input features may involve altering one or more process operation recipes, which may reduce the usefulness of results. Utilizing measurements of many substrates for modeling may involve expending time, energy, processing power, etc., to model some essentially identical processes without gaining substantive new information. Utilizing measurements of many substrates as input for process modeling may be subject to some similar shortcomings as using one or a few substrates. For example, particular combinations of parameters/shapes of features may not be included in a sample set, differences between neighboring features or features of the same substrate may occlude causes of results of the modeling, and so on.

Systems and methods of the current disclosure may address one or more of these shortcomings of conventional methods. In some embodiments, measurements of one or more substrates are provided. The measurements may be generated by one or more metrology tools. The measurements may be obtained from one or more microscopy images. The measurements may be obtained from one or more scanning electron microscope (SEM) images, one or more cross-sectional scanning electron microscope (XSEM) images, and/or one or more transmission electron microscope (TEM) images, for example.

Measurements of one or more features of the one or more substrates may be extracted from the microscopy images. The one or more substrates may include one or more features. Features may include structures, shapes, profiles, or the like, of the substrates. Features may include gates, holes, trenches, masks, spacers, or any other characteristic that may be on a substrate of interest. Measurements of a feature may include data points indicating the boundaries of the feature, a function fit to the shape of the feature, measurements of the size of one or more shapes or portions of a feature, or the like. Measurements of one or more features may be taken from partially processed substrates, e.g., substrates upon which some processing operations of a process recipe have been performed and other processing operations have not yet been performed. Measurements of one or more features may be taken from completed substrates, e.g., substrate that have undergone all processing operations of a process recipe. Microscopy images from which to extract feature measurements may be taken from partially completed or completed substrates.

In some embodiments, measurements of the one or more features are supplied to a model configured to generate measurements of a standard feature. The standard feature may be generated by performing a statistical analysis based of measurements of the one or more features. The measurements of the standard feature may be an average of the measurements of a plurality of features. The plurality of features may be nominally identical, e.g., the process recipe associated with production of a substrate may be targeted toward generating an array of identical features. The features of the substrates and/or the measurements of the features may not be identical, e.g., due to differences in processing conditions, measurement accuracy, or the like. Generating measurements of a standard feature may include generating measurements of a feature likely to be generated by the substrate processing procedure. Generating measurements of a standard feature may include generating measurements of a feature probable to be generated by the substrate processing procedure. Generating measurements of a standard feature may include selecting measurements of a feature of a substrate to designate as standard. Generating measurements of a standard feature may include selecting a number of measurements each from a number of features measured to combine and designate as measurements of a standard feature. Generating measurements of a standard feature may include generating measurements that are not associated with a measured feature. Generating measurements of a standard feature may include a statistical analysis of features. Generating measurements that are not associated with a measured feature may include generating an average, median, and/or ideal set of measurements to act as a standard feature from a plurality of measurements of features.

In some embodiments, one or more characteristics of the standard feature are parameterized. Slopes of portions of a feature, sizes of portions of a feature, radii of curvature of portions of a feature, or the like may be parameterized. Parameterization may be performed manually. Parameterization may be performed by a model. Parameterization may be performed by a machine learning model. Parameterization may include parameterizing characteristics of the standard feature that include variations between the plurality of features used to generate the standard feature. Parameterization may enable generation of variations of the standard feature. For example, each parameter may have an associated range. The range may be generated from a statistical metric associated with the plurality of features utilized to generate the standard feature, such as a number of standard deviations from the average of the parameter values of the characteristic of the plurality of features, an inner quartile, a range, or another metric. A statistical analysis may be performed to determine a range of parameters. The range may be generated and/or adjusted manually. Combinations of values of parameters within the associated ranges may be utilized in a systematic or random manner to generate a plurality of parameterizations of features. The plurality of parameterizations of features may substantially span a space of probable feature shapes.

Each of the plurality of parameterizations of features (e.g., each uniquely shaped feature) may be used to generate an array of identical features. The array may be 2-dimensional. The array may be 3-dimensional. Each array of identical features may be provided to a process model. The process model may digitally perform one or more process operations on a virtual substrate comprising the array of features. For example, the process model may perform a deposition operation, an etch operation, or the like, upon the substrate including the array of identical features. For example, the process model may model deposition of material upon a surface of a substrate, in a hole of a substrate, or the like. One or more outputs of interest may be extracted from the process model, such as thickness of a deposition layer at one or more locations, width of an etched hole at one or more depths, or the like. In some embodiments, one or more virtual substrates including an array of features that are not identical may be generated and provided to the process model.

An input/output mapping may be generated from the results of the process model. The input/output mapping may be generated by a fit model. The input/output mapping may be generated by a machine learning model. The input/output mapping may include a set or list of inputs to the process model correlated to output results of the process model. The input/output mappings may include a combination of inputs likely to produce a substrate with target output qualities. Inputs of the input/output mapping may include parameters of features of a substrate. Inputs of the input/output mappings may include measurements of characteristics of features of a substrate.

A corrective action may be performed in view of the input/output mappings. An input/output mapping may inform a target input substrate geometry to a process operation to achieve a target output of the process operation. One or more corrective actions may be performed, e.g., to achieve an input profile or feature shape to a process operation to facilitate the target output after the process operation is performed. Corrective actions may include updating a process recipe. Corrective actions may include performing maintenance of a process chamber and/or one or more chamber components of a process chamber. Corrective actions may include scheduling maintenance of one or more chamber components. Corrective actions may include providing an alert to a user. Corrective actions may include performing and/or scheduling a cleaning or seasoning operation for the process chamber.

Aspects of the present disclosure provide technical advantages over conventional methods. Utilizing metrology data of one or more substrates for generating a virtual substrate to provide to a process model may be an improvement over other methods. Modeling a process operation may be expensive, in terms of time, processing power, energy, etc. Modeling a substrate for input into a process model may include simulating multiple process operations, compounding the costs of modeling. Utilizing metrology data (e.g., microscopy images) as a base for modeling a substrate to provide to a process model may reduce the cost compared to modeling the process operations to generate the substrate.

Utilizing measurements of a plurality of features to generate a standard feature may improve accuracy and/or applicability of results of a process model. A substrate may include an array of slightly different features. Differences may arise from differences in processing conditions. Differences in features of a simulated substrate may arise from variations in measurements of various features. Differences in virtual features of a simulated substrate (e.g., differences between features expressed in data provided to a process model) may interfere with interpreting results of the model. It may be expensive, in terms of modeling and/or measuring additional substrate, performing additional process modeling, and the like, to separate effects due to differences in features from effects caused by design of the features.

Parameterizing a standard feature and generating multiple arrays of features based on varying the parameters of the standard feature may improve learning and enable further process improvement than conventional methods. Conventional methods may rely upon measured or process-modeled features for generating input/output mappings for a process operation. By parameterizing a standard feature, substrates including variations of the feature may be generated and provided to a process model in a systematic and/or random manner, e.g., that approximately span an applicable space of feature geometries. Input/output mappings may be generated by exploiting known changes to feature geometry based on parameters of the feature. Testing of different feature shapes, optimization of feature shapes for input to a process operations, and the like may be easily performed by adjusting parameters of a standard feature, generating a substrate including an array of the adjusted feature, and providing the substrate to a process model.

Performing one or more corrective actions in view of input/output mappings in accordance with methods of this disclosure may improve properties of a processed substrate. Optimizing an input substrate to a process operation may increase the likelihood of generating an output from the process operation that satisfies one or more performance targets. Improving a process recipe, process chamber, or the like in view of input/output mappings has the advantages of reducing time, energy, chamber wear, chamber maintenance, chamber maintenance time, replacement components, materials, and/or cost of disposal associated with generating products that do not meet target performance standards.

In one aspect of the present disclosure, a method includes receiving profile data of a plurality of features of a substrate. The method further includes generating a typical profile based on the profile data of the plurality of features. The method further includes generating a first array of features. Each of the first array of features is based on the typical profile. The method further includes providing the first array of features to a process model. The method further includes obtaining first output from the process model based on the first array of features. The method further includes causing performance of a corrective action in view of the first output from the process model.

In another aspect of the disclosure, a system includes memory and a processing device coupled to the memory. The processing device is to perform operations. The operations include receiving profile data of a plurality of features of a substrate. The operations further include generating a typical profile based on the profile data of the plurality of features. The operations further include generating a first array of features. Each of the first array of features is based on the typical profile. The operations further include providing the first array of features to a process model. The operations further include obtaining first output from the process model based on the first array of features. The operations further include causing performance of a corrective action in view of the first output from the process model.

In another aspect of the disclosure, a non-transitory machine-readable storage medium stores instructions. When executed, the instructions cause a processing device to perform operations. The operations include receiving profile data of a plurality of features of a substrate. The operations further include generating a typical profile based on the profile data of the plurality of features. The operations further include generating a first array of features. Each of the first array of features is based on the typical profile. The operations further include providing the first array of features to a process model. The operations further include obtaining first output from the process model based on the first array of features. The operations further include causing performance of a corrective action in view of the first output from the process model.

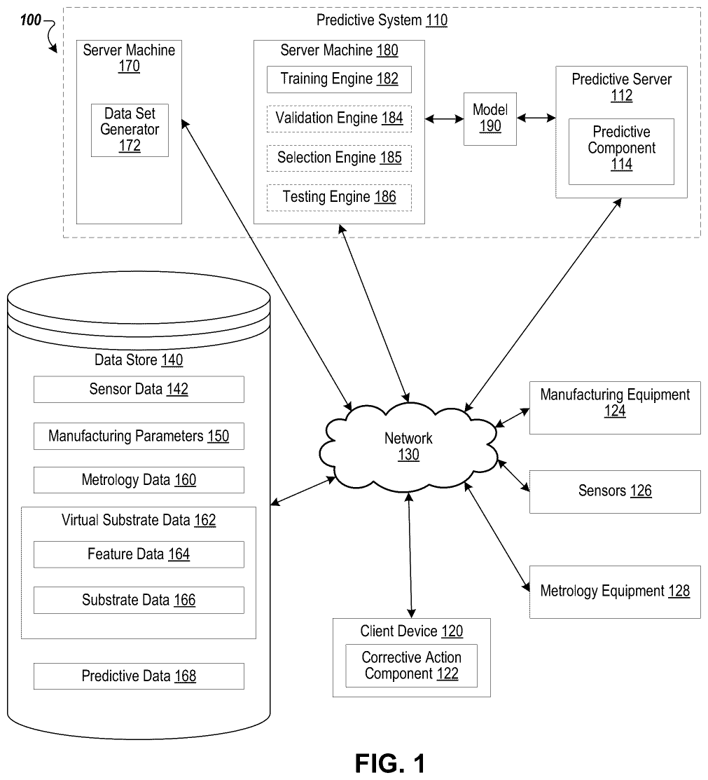

FIG. 1 is a block diagram illustrating an exemplary system 100 (exemplary system architecture), according to some embodiments. The system 100 includes a client device 120, manufacturing equipment 124, sensors 126, metrology equipment 128, predictive server 112, and data store 140. The predictive server 112 may be part of predictive system 110. Predictive system 110 may further include server machines 170 and 180.

Sensors 126 may provide sensor data 142 associated with manufacturing equipment 124 (e.g., associated with producing, by manufacturing equipment 124, corresponding products, such as substrates). Sensor data 142 may be used to ascertain equipment health and/or product health (e.g., product quality). Manufacturing equipment 124 may produce products following a recipe or performing runs over a period of time. In some embodiments, sensor data 142 may include values of one or more of optical sensor data, spectral data, temperature (e.g., heater temperature), spacing (SP), pressure, High Frequency Radio Frequency (HFRF), radio frequency (RF) match voltage, RF match current, RF match capacitor position, voltage of Electrostatic Chuck (ESC), actuator position, electrical current, flow, power, voltage, etc. Sensor data (e.g., a portion of the sensor data 142) may be associated with a product currently being processed, a product recently processed, a number of recently processed products, etc. Sensor data may include data stored associated with previously produced products. Sensor data 142 may include attribute data, label of a state of manufacturing equipment, etc. Examples of attribute data include labels of manufacturing equipment ID or design, sensor ID, type, and/or location. Examples of labels of a state of manufacturing equipment include a present fault, a service lifetime, and so on.

Sensor data 142 may be associated with, correlated to, and/or indicative of manufacturing parameters such as hardware parameters of manufacturing equipment 124 or process parameters of manufacturing equipment 124. Examples of hardware parameters include hardware settings or installed components, such as size, type, etc. of installed components. Examples of process parameters include heater settings, gas flow settings, pressure settings, and so on. Data associated with some hardware parameters and/or process parameters may, instead or additionally, be stored as manufacturing parameters 150. The manufacturing parameters 150 may include historical manufacturing parameters (e.g., associated with historical processing runs) and current manufacturing parameters. Manufacturing parameters 150 may be indicative of input settings to the manufacturing device (e.g., heater power, gas flow, etc.). Sensor data 142 and/or manufacturing parameters 150 may be provided while the manufacturing equipment 124 is performing manufacturing processes (e.g., equipment readings while processing products). Sensor data 142 may be different for each product (e.g., each substrate). Substrates may have property values measured by metrology equipment 128. Examples of property values include film thickness, film strain, critical dimension, optical properties, electrical properties, etc. The properties values may be measured at a standalone metrology facility, measured by an integrated or inline metrology system, or the like. Metrology data 160 may be a component of data store 140. Metrology data 160 may include historical metrology data (e.g., metrology data associated with previously processed products).

In some embodiments, metrology data 160 may be provided without use of a standalone metrology facility. For example, metrology data 160 may be in-situ metrology data (e.g., metrology or a proxy for metrology collected during processing), integrated metrology data (e.g., metrology or a proxy for metrology collected while a product is within a chamber or under vacuum, but not during processing operations), inline metrology data (e.g., data collected after a substrate is removed from vacuum), etc. Metrology data 160 may include current metrology data (e.g., metrology data associated with a product currently or recently processed).

Metrology equipment 128 may include microscopy and/or imaging equipment. Metrology equipment 128 may include one or more devices for obtaining an image of a substrate, of a portion of a substrate, of features of a substrate, or the like. Metrology equipment 128 may include SEM equipment, XSEM equipment, TEM equipment, and/or other forms of imaging and microscopy equipment. Metrology data 160 may include image data, microscopy data, and the like.

In some embodiments, sensor data 142, metrology data 160, or manufacturing parameters 150 may be processed (e.g., by the client device 120 and/or by the predictive server 112). Processing of the sensor data 142 may include generating features. In some embodiments, the features are a pattern in the sensor data 142, metrology data 160, and/or manufacturing parameters 150. Examples of such features include slope, width, height, peak, etc. In some embodiments, the features are a combination of values from the sensor data 142, metrology data, and/or manufacturing parameters. Examples of such features include power derived from voltage and current, etc. Sensor data 142 may include features, and the features may be used by predictive component 114 for performing signal processing and/or for obtaining predictive data 168 for performance of a corrective action.

Each instance (e.g., set) of sensor data 142 may correspond to a product (e.g., a substrate), a set of manufacturing equipment, a type of substrate produced by manufacturing equipment, or the like. Each instance of metrology data 160 and manufacturing parameters 150 may likewise correspond to a product, a set of manufacturing equipment, a type of substrate produced by manufacturing equipment, or the like. The data store may further store information associating sets of different data types, e.g. information indicative that a set of sensor data, a set of metrology data, and a set of manufacturing parameters are all associated with the same product, manufacturing equipment, type of substrate, etc.

Data store 140 may further include virtual substrate data 162. Virtual substrate data 162 may include data related to simulated, synthetic, and/or virtual substrates. Virtual substrate data 162 may include measurements of features, parameters of features, images of features, etc. Various characteristics and representations of features may be stored as feature data 164. Virtual substrate data 162 may include measurements, parameters, and/or images of simulated substrates. Characteristics and representations of simulated and/or virtual substrates may be stored as substrate data 166. Substrate data 166 may include 2-dimensional and/or 3-dimensional arrays of features.

In some embodiments, predictive system 110 may generate predictive data 168. Predictive data 168 may be generated utilizing one or more models, such as physics-based models, deposition models, machine learning models, etc. Predictive data 168 may include output of a process model. Predictive data 168 may include predicted results of one or more process operations applied to a virtual substrate. Predictive data 168 may include predicted shortcomings of a process operation, recipe, or equipment. Predictive data 168 may include recommended corrective actions, e.g., corrective action data. Operations of predictive system 110 may include the use of one or more supervised models, which are trained using input data labeled with target outcome data. Operations of predictive system 110 may include the use of one or more unsupervised models, which are trained using input data that is not labeled with target output. Operations of predictive system 110 may include the use of one or more semi-supervised models, which include a mix of labeled and unlabeled input data in training.

Client device 120, manufacturing equipment 124, sensors 126, metrology equipment 128, predictive server 112, data store 140, server machine 170, and server machine 180 may be coupled to each other via network 130 for generating predictive data 168 to perform corrective actions. In some embodiments, network 130 may provide access to cloud-based services. Operations performed by client device 120, predictive system 110, data store 140, etc., may be performed by virtual cloud-based devices.

In some embodiments, network 130 is a public network that provides client device 120 with access to the predictive server 112, data store 140, and other publicly available computing devices. In some embodiments, network 130 is a private network that provides client device 120 access to manufacturing equipment 124, sensors 126, metrology equipment 128, data store 140, and other privately available computing devices. Network 130 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

Client device 120 may include computing devices such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. Client device 120 may include a corrective action component 122. Corrective action component 122 may receive user input (e.g., via a Graphical User Interface (GUI) displayed via the client device 120) of an indication associated with manufacturing equipment 124. In some embodiments, corrective action component 122 transmits the indication to the predictive system 110, receives output (e.g., predictive data 168) from the predictive system 110, determines a corrective action based on the output, and causes the corrective action to be implemented. In some embodiments, corrective action component 122 obtains sensor data 142 associated with manufacturing equipment 124 (e.g., from data store 140, etc.) and provides sensor data 142 associated with the manufacturing equipment 124 to predictive system 110.

In some embodiments, metrology data 160 may be provided to predictive system 110, predictive server 112, predictive component 114, model 190, or the like. Metrology data 160 may be retrieved from data store 140 by corrective action component 122 and provided to predictive system 110. Predictive system 110 may produce as output feature data 164, substrate data 166, and/or predictive data 168, any of which may be stored in data store 140. Client device 120 (e.g., via corrective action component 122) may retrieve output of predictive system 110 and provide the output to data store 140. In some embodiments, corrective action component 122 stores data to be used as input to a machine learning, physics-based, or other in data store 140. In some embodiments, a component of predictive system 110 (e.g., predictive server 112, server machine 170) retrieves the input data from data store 140. In some embodiments, predictive server 112 may store output (e.g., predictive data 168) of the trained model(s) 190 in data store 140 and client device 120 may retrieve the output from data store 140.

In some embodiments, corrective action component 122 receives an indication of a corrective action from the predictive system 110 and causes the corrective action to be implemented. Each client device 120 may include an operating system that allows users to one or more of generate, view, or edit data. The data may include, for example, an indication associated with manufacturing equipment 124, corrective actions associated with manufacturing equipment 124, etc. Client device 120 may include components or systems for providing an alert to a user. The alert may be an alert of a potential shortcoming of a process operation, process procedure, process recipe, process equipment, etc.

In some embodiments, metrology data 160 corresponds to historical property data of products (and predictive data 168 is associated with predicted property data. Historical property data of products may include data for products processed using manufacturing parameters associated with historical sensor data and historical manufacturing parameters. Predicted property data may include data of products to be produced or that have been produced in conditions recorded by current sensor data and/or current manufacturing parameters. In some embodiments, predictive data 168 is or includes predicted metrology data (e.g., virtual metrology data, virtual synthetic microscopy images) of the products to be produced or that have been produced according to conditions recorded as current sensor data, current measurement data, current metrology data and/or current manufacturing parameters. Predictive data 168 may include results of providing a simulated substrate to a process model. Predictive data 168 may include predictions of results of applying a process operation to a substrate. Predictive data 168 may include mapping data. Mapping data may include correlating properties of an input substrate to properties of an output substrate of a process operation. Mapping data may include predicting properties of an output substrate of a process operation based on properties of an input substrate. Substrate properties may include parameters, features, feature profiles, dimensions, etc. In some embodiments, predictive data 168 is or includes an indication of any abnormalities and optionally one or more causes of the abnormalities. Abnormalities may include abnormal products, abnormal components, abnormal equipment, abnormal material or energy usage, etc. In some embodiments, predictive data 168 is an indication of change over time or drift in some component of manufacturing equipment 124, sensors 126, metrology equipment 128, or the like. In some embodiments, predictive data 168 is an indication of an end of life of a component of manufacturing equipment 124, sensors 126, metrology equipment 128, or the like. In some embodiments, predictive data 168 is an indication of progress of a processing operation being performed. In some embodiments, predictive data 168 may be used for process control.

Performing manufacturing processes that result in defective products can be costly in time, energy, products, components, manufacturing equipment 124, the cost of identifying the defects and discarding the defective product, etc. By inputting metrology data 1602 (e.g., measurement extracted from a TEM or XSEM image of a substrate) into predictive system 110, receiving output of predictive data 168, and performing a corrective action based on the predictive data 168, system 100 can have the technical advantage of avoiding the cost of producing, identifying, and discarding defective products. System 100 may increase a likelihood of generating substrates with properties within target thresholds. By increasing a likelihood of generating substrates with properties within target thresholds, cost of production per successful substrate may be reduced. Cost of production may be reduced in areas of production time, material, energy, equipment component wear, increase of process chamber down time, increased maintenance costs, etc.

Performing manufacturing processes that result in failure of the components of the manufacturing equipment 124 can be costly in downtime, damage to products, damage to equipment, express ordering replacement components, etc. Systems and/or methods of the current disclosure may alleviate one or more of these deficiencies. By inputting virtual substrates based on measured feature properties to a model, receiving output, and performing corrective actions, system 100 may have a technical advantage over conventional systems. Virtual substrates may be based on metrology data 160. Virtual substrates may be generated based on one or more microscopy images. Corrective actions may include predicted operational maintenance. Corrective actions may include replacement, processing, cleaning, etc., of components. System 100 may have the technical advantage of avoiding costs of unexpected component failure. System 100 may have the advantage of avoiding the cost of unscheduled downtime. System 100 may have the advantage of avoiding the cost of productivity loss to equipment downtime. System 100 may have the advantage of avoiding the cost of product scrap. System 100 may avoid further costs in addition to these by utilizing systems and/or methods of this disclosure. Differences between predicted properties of substrates and measured properties may include indications of drifting, aging, or failing equipment. Monitoring the performance over time of components, e.g. manufacturing equipment 124, sensors 126, metrology equipment 128, and the like, may provide indications of degrading components.

Manufacturing parameters may be suboptimal for producing product which may have costly results of increased resource (e.g., energy, coolant, gases, etc.) consumption, increased amount of time to produce the products, increased component failure, increased amounts of defective products, etc. By inputting indications of metrology into predictive system 110 and using output data to perform a corrective action, system 100 may have technical advantages over conventional methods. Indications of metrology may include virtual substrates. Virtual substrates may be based on measured features of substrates. Output of predictive system 110 may include predictive data 168. Corrective actions may include updating manufacturing parameters. Updating manufacturing parameters may include setting optimal manufacturing parameters for generating a product. System 100 may have the technical advantage of utilizing more advantageous manufacturing parameters. The manufacturing parameters may include hardware parameters, process parameters, input substrate properties, etc. System 100 may avoid costly results of utilizing suboptimal manufacturing parameters.

Corrective actions may be associated with one or more types of process control. Process control may include Computational Process Control (CPC), Statistical Process Control (SPC), Advanced Process Control (APC), model-based process control, etc. SPC may include control of electronic components to determine process progress. SPC may include predicting a useful lifespan of components. SPC may include comparing data to historical data, such as comparing trace data to historical data to determine if the trace data is within a 3-sigma window of an average. Corrective actions may be related to preventative operative maintenance, design optimization, updating of manufacturing parameters, updating manufacturing recipes, feedback control, machine learning modification, or the like.

In some embodiments, the corrective action includes providing an alert to a user. The alert may include an alarm to stop or not perform a manufacturing process. The alert may be provided if predictive data 168 indicates an abnormality. The alert may be provided if predictive data 168 indicates an abnormal product, component, equipment, etc. In some embodiments, performance of the corrective action includes causing updates to one or more manufacturing parameters. In some embodiments performance of a corrective action may include retraining a machine learning model associated with manufacturing equipment 124. Performance of a corrective action may include updating of other types of models associated with manufacturing equipment 124, such as adjusting a physics-based model, a process model, or the like. In some embodiments, performance of a corrective action may include training a new machine learning model and/or developing a new physics-based or process model associated with manufacturing equipment 124.

Manufacturing parameters 150 may include hardware parameters and/or process parameters. Hardware parameters may include information indicative of which components are installed in the manufacturing system, indications of component age, indication of software version or updates, etc. Process parameters may include temperature, pressure, gas flow rate, electrical current, voltage, lift speed, etc. In some embodiments, the corrective action includes causing preventative operative maintenance. Preventative operative maintenance may include replacing, processing, cleaning, etc., components of the manufacturing system. In some embodiments, the corrective action includes causing design optimization. Design optimization may include updating manufacturing parameters, updating manufacturing processes, and/or updating manufacturing equipment to improve performance of the manufacturing system. In some embodiments, the corrective action includes a updating a recipe. Altering a recipe may include altering the timing of manufacturing subsystems entering an idle or active mode, altering set points of various property values, or the like.

Predictive server 112, server machine 170, and server machine 180 may each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc. Operations of predictive server 112, server machine 170, server machine 180, data store 140, etc., may be performed by a cloud computing service, cloud data storage service, etc.

Predictive server 112 may include a predictive component 114. In some embodiments, the predictive component 114 may receive metrology data 160 and generate output for performing corrective action associated with the manufacturing equipment 124 based on the current data. Metrology data 160 may be received from client device 120, retrieved from data store 140, etc. Output of predictive component 114 may be predictive data 168. In some embodiments, predictive data 168 may include one or more predicted dimension measurements of a processed product. In some embodiments, predictive component 114 may use one or more trained machine learning models 190 to determine the output for performing the corrective action based on current data.

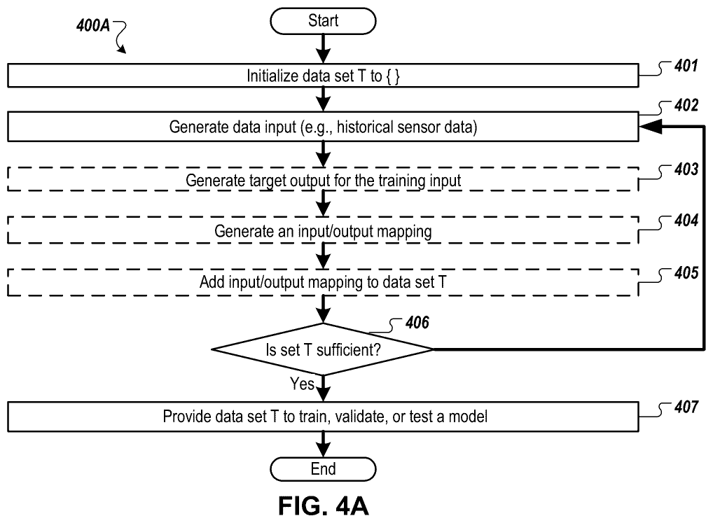

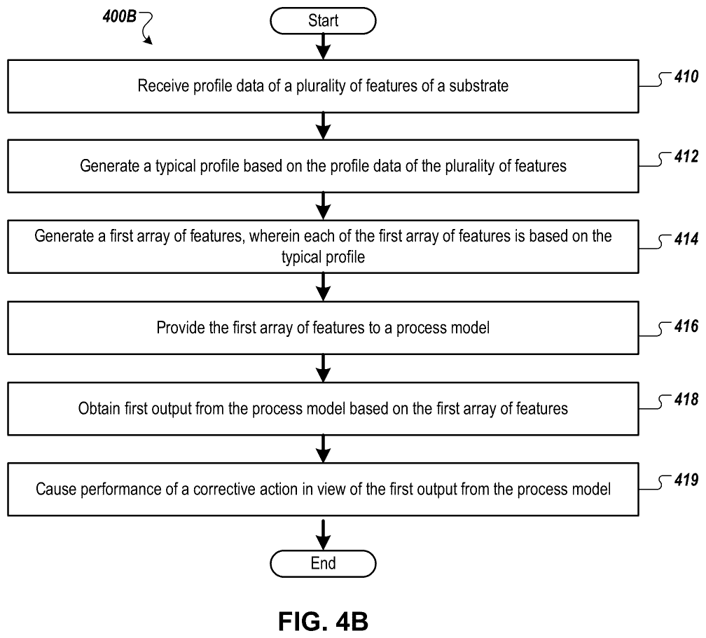

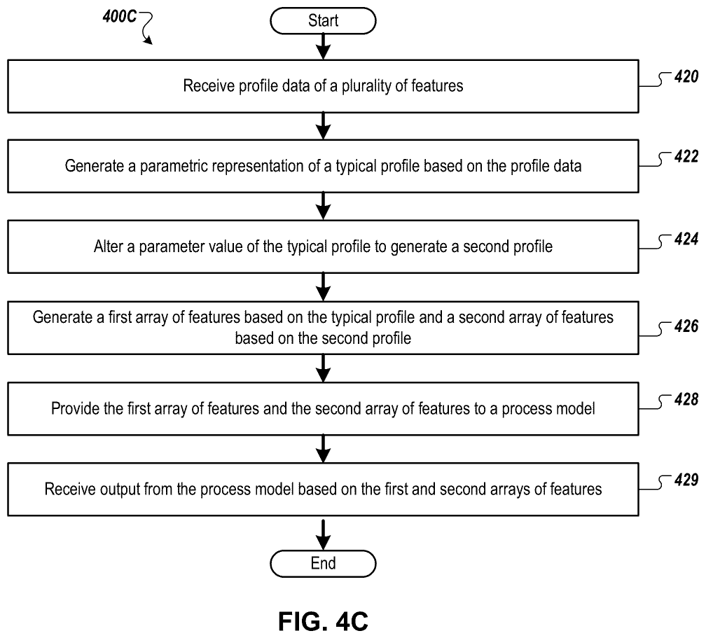

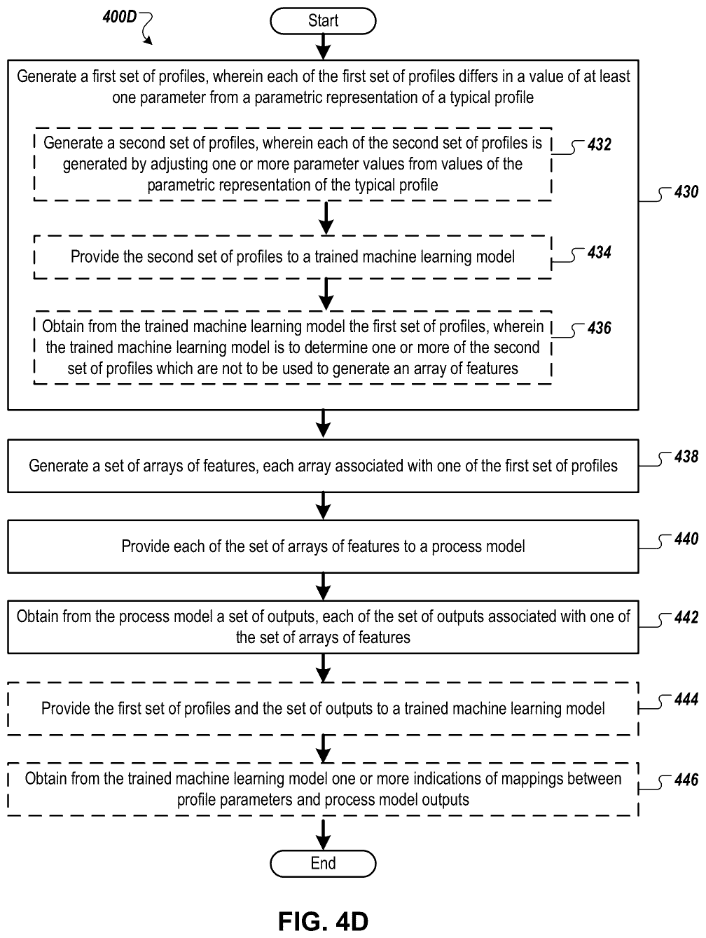

In some embodiments, predictive server 110 may receive metrology data 160 (e.g., measurements of one or more substrates) and generate as output feature data 164. The output feature data may include a standard feature. More information on generating a standard feature is discussed in connection with FIG. 4B. Predictive system 110 may receive feature data 164 (e.g., measurements of a standard feature, parameters of a standard feature, measurement or parameters of a non-standard feature, etc.) and generate as output one or more virtual substrates. The virtual substrates may be stored as substrate data 166. Predictive system 110 may receive one or more virtual substrates, and generate output. The output may be stored as predictive data 168. The output may include predicted properties of the substrate after a process operation is performed on the substrate. The output may include one or more effects that properties of the input substrate have on the output substrate. The output may include input/output mappings, in the forms of data points, data trends, a multi-dimensional fit, or the like.

Manufacturing equipment 124 may be associated with one or more machine leaning models, e.g., model 190. Machine learning models associated with manufacturing equipment 124 may perform many tasks, including process control, classification, performance predictions, etc. Model 190 may be trained using data associated with manufacturing equipment 124 or products processed by manufacturing equipment 124, e.g., sensor data 142 (e.g., collected by sensors 126), manufacturing parameters 150 (e.g., associated with process control of manufacturing equipment 124), metrology data 160 (e.g., generated by metrology equipment 128), etc.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs).

A recurrent neural network (RNN) is another type of machine learning model. A recurrent neural network model is designed to interpret a series of inputs where inputs are intrinsically related to one another, e.g., time trace data, sequential data, etc. Output of a perceptron of an RNN is fed back into the perceptron as input, to generate the next output.

Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. In an image recognition application, for example, the raw input may be a matrix of pixels; the first representational layer may abstract the pixels and encode edges; the second layer may compose and encode arrangements of edges; the third layer may encode higher level shapes (e.g., teeth, lips, gums, etc.); and the fourth layer may recognize a scanning role. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

In some embodiments, predictive component 114 and/or model 190 may include a process model. The process model may predict the outcome of performing one or more process operations. The process model may be a physics-based model, a simulation model, a machine learning model, etc.

In some embodiments, predictive component 114 and/or model 190 may include a model for generating parameterization of a feature. The model may be a machine learning model. The model may receive as input a number of measurements of a plurality of features, statistical metrics related to measurements of a plurality of features, measurements of a standard feature, or the like. The model may determine which characteristics of a feature to parameterize, e.g., based on characteristics that vary between the measured features. Characteristics may include rounding radii (e.g., top of a gate, corner of a sidewall, bottom of a hole, etc.), slopes (e.g., slope of a sidewall), length, critical dimension, or other characteristics of a feature.

In some embodiments, predictive component 114 and/or model 190 include a model for generating combinations of parameter values for modeling. Some characteristics of a feature may be parameterized. One or more parameters of a feature may be adjusted to generate an updated feature. For example, parameters may be adjusted to generate a feature which has a different shape, different dimensions, etc., than a standard feature. Some parameter values may be impossible, improbable, or unprofitable for substrate production. Some combinations of parameter values may be impossible to produce, may be unprofitable, may not generate a substrate having target properties or performance, etc. Parameterization of a feature may be provided to a model, and the model may be configured to determine which combinations of parameter values are likely to yield valuable information under further analysis. For example, the model may determine which combinations of parameters are impossible or unlikely to correlate to a physical structure, which are unlikely to generate favorable results, which are cost-prohibitive to generate, etc. The model may be a physics-based model, a simulation model, a machine learning model, etc.

In some embodiments, predictive component 114 and/or model 190 include a model for input/output mapping. Predictive system 110 may be configured to perform operations to generate multiple virtual substrates, each including an array of features, and provide the substrates to a process model. Differences between substrates provided to the process model may be correlated to differences in output results of the process model. For example, there may be input/output mappings associated with the procedures of predictive system 110. A model may be utilized to extract input/output mappings from the input and output data of the process model. A model may be utilized to provide a number of impactful input parameters on output results. A model may be utilized to generate an input design (e.g., feature parameters, feature shape, etc.) that is likely to generate a target output. For example, a model may be utilized to optimize input parameters for generating target output parameters. Models such as these may be physics-based models, transformation models such as principle component analysis models, machine learning models, etc.

In some embodiments, predictive component 114 receives metrology data 160, performs signal processing to break down the data into sets of data, provides the sets of current data as input to a trained model 190, and obtains outputs indicative of predictive data 168 from the trained model 190. In some embodiments, predictive component 114 receives metrology data (e.g., predicted metrology data based on sensor data) of a substrate and provides the metrology data to trained model 190. Model 190 may be configured to accept data indicative of substrate metrology and generate as output predictive input/output mapping data. In some embodiments, predictive data is indicative of metrology data (e.g., prediction of substrate quality). In some embodiments, predictive data is indicative of component health.

In some embodiments, the various models discussed in connection with model 190 may be combined in one model, or may be separate models. For example, supervised machine learning models, unsupervised machine learning models, and/or physics-based models may be combined into one or more ensemble models.

Data may be passed back and forth between several distinct models included in model 190 and predictive component 114. In some embodiments, some or all of these operations may instead be performed by a different device, e.g., client device 120, server machine 170, server machine 180, etc. It will be understood by one of ordinary skill in the art that variations in data flow, which components perform which processes, which models are provided with which data, and the like are within the scope of this disclosure.

Data store 140 may be a memory (e.g., random access memory), a drive (e.g., a hard drive, a flash drive), a database system, a cloud-accessible memory system, or another type of component or device capable of storing data. Data store 140 may include multiple storage components (e.g., multiple drives or multiple databases) that may span multiple computing devices (e.g., multiple server computers). The data store 140 may store sensor data 142, manufacturing parameters 150, metrology data 160, virtual substrate data 162, and predictive data 168.

Sensor data 142 may include historical sensor data and/or current sensor data. Sensor data may include sensor data time traces over the duration of manufacturing processes, associations of data with physical sensors, pre-processed data, such as averages and composite data, and data indicative of sensor performance over time (i.e., many manufacturing processes). Manufacturing parameters 150 and metrology data 160 may contain similar features. For example, metrology data 160 may include historical metrology data and/or current metrology data. Historical sensor data, historical metrology data, and historical manufacturing parameters may be historical data. At least a portion of historical data may be used for training model 190. Current sensor data, current metrology data, may be current data for which predictive data 168 is to be generated. Current data may be provided as input to one or more trained models. Predictive data 168 may be used for performing one or more corrective actions. Virtual substrate data 162 may include data related to generating virtual, synthetic, and/or digital substrates, for providing to a process model to generate process model output. Virtual substrate data 162 may include data indicative of features, feature characteristics, feature parameterization, substrates, substrates including arrays of features, etc.

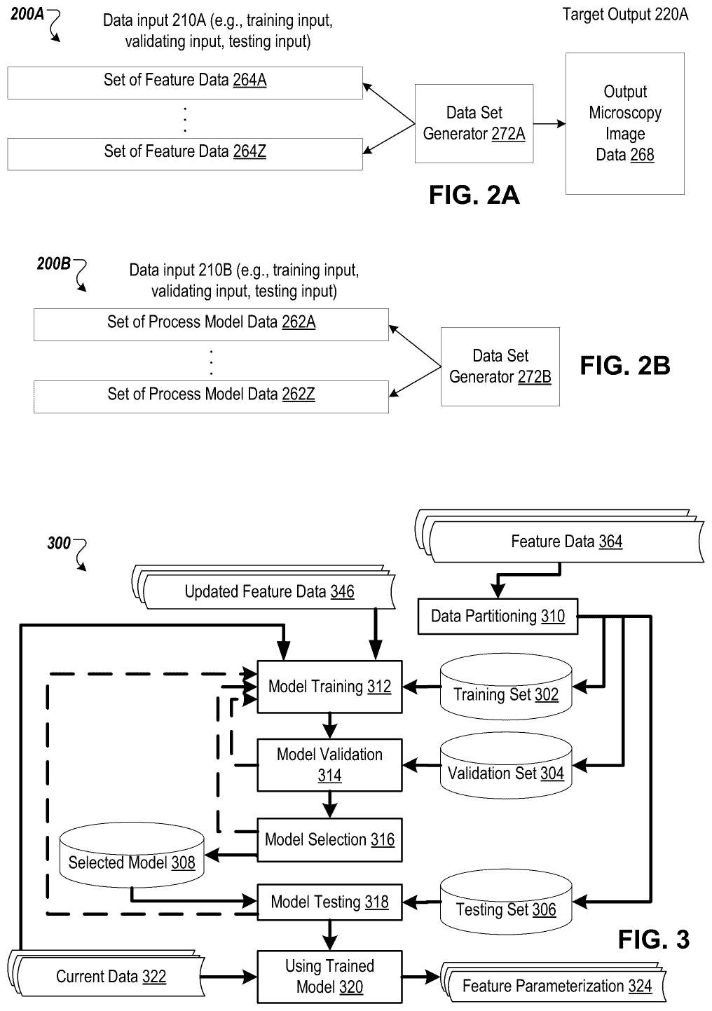

In some embodiments, predictive system 110 further includes server machine 170 and server machine 180. Server machine 170 includes a data set generator 172 that is capable of generating data sets to train, validate, and/or test model(s) 190. Data set generator 172 may generate data sets for models, including one or more machine learning models. Data sets may include a set of data inputs. Data sets may include a set of target outputs. Some operations of data set generator 172 are described in detail below with respect to FIGS. 2A-2B and 4A. In some embodiments, data set generator 172 may partition the historical data into a training set, a validating set, and a testing set. For example, a training set may include sixty percent of the historical data used to generate a model. A validating set may include twenty percent of the historical data used to generate a model. A testing set may include twenty percent of the historical data used to generate a model.

In some embodiments, predictive system 110 (e.g., via predictive component 114) generates multiple sets of attributes. Attributes may be related to partitioning or pre-processing of data input to a machine learning model. For example a first set of attributes may correspond to a first set of types of sensor data that correspond to each of the data sets and a second set of attributes may correspond to a second set of types of sensor data that correspond to each of the data sets. A set of attributes may include data such as sensor data from a set of sensors, a set of metrology measurements, etc. A set of attributes may include a combination of values from a set of measurements. A set of attributes may include patterns in values from a first set of measurements. Each of the training, validation, and/or testing data sets may use the same set of attributes to train, validate, and/or test a model.

In some embodiments, machine learning model 190 is provided historical data as training data. In some embodiments, machine learning model 190 is provided with virtual substrate data, synthetic substrate data, or the like as training data. The historical and/or synthetic data may be or include microscopy image data in some embodiments. The type of data provided will vary depending on the intended use of the machine learning model. For example, a machine learning model may be trained by providing the model with a set of feature parameters as training input and indications of unphysical combinations of parameters as target output. In some embodiments, a large volume of data is used to train model 190, e.g., sensor and metrology data of hundreds of substrates may be used

Server machine 180 includes a training engine 182, a validation engine 184, selection engine 185, and/or a testing engine 186. An engine (e.g., training engine 182, a validation engine 184, selection engine 185, and a testing engine 186) may refer to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 may be capable of training a model 190 using one or more sets of features associated with the training set from data set generator 172. The training engine 182 may generate multiple trained models 190, where each trained model 190 corresponds to a distinct set of attributes of the training set (e.g., sensor data from a distinct set of sensors, a subset of metrology measurements, etc.). For example, a first trained model may have been trained using all attributes (e.g., X1-X5), a second trained model may have been trained using a first subset of the attributes (e.g., X1, X2, X4), and a third trained model may have been trained using a second subset of the attributes (e.g., X1, X3, X4, and X5) that may partially overlap the first subset of features. Data set generator 172 may receive the output of a trained model, collect that data into training, validation, and testing data sets, and use the data sets to train a second model.

Validation engine 184 may be capable of validating a trained model 190 using a corresponding set of attributes of the validation set from data set generator 172. For example, a first trained machine learning model 190 that was trained using a first set of attributes of the training set may be validated using the first set of attributes of the validation set. The validation engine 184 may determine an accuracy of each of the trained models 190 based on the corresponding sets of attributes of the validation set. Validation engine 184 may discard trained models 190 that have an accuracy that does not meet a threshold accuracy. In some embodiments, selection engine 185 may be capable of selecting one or more trained models 190 that have an accuracy that meets a threshold accuracy. In some embodiments, selection engine 185 may be capable of selecting the trained model 190 that has the highest accuracy of the trained models 190.

Testing engine 186 may be capable of testing a trained model 190 using a corresponding set of attributes of a testing set from data set generator 172. For example, a first trained machine learning model 190 that was trained using a first set of attributes of the training set may be tested using the first set of attributes of the testing set. Testing engine 186 may determine a trained model 190 that has the highest accuracy of all of the trained models based on the testing sets.

In the case of a machine learning model, model 190 may refer to the model artifact that is created by training engine 182 using a training set that includes data inputs and corresponding target outputs (correct answers for respective training inputs). Patterns in the data sets can be found that map the data input to the target output (the correct answer), and machine learning model 190 is provided mappings that capture these patterns. The machine learning model 190 may use one or more of Support Vector Machine (SVM), Radial Basis Function (RBF), clustering, supervised machine learning, semi-supervised machine learning, unsupervised machine learning, k-Nearest Neighbor algorithm (k-NN), linear regression, random forest, neural network (e.g., artificial neural network, recurrent neural network), etc.

In some embodiments, one or more machine learning models 190 may be trained using historical data (e.g., historical metrology data). In some embodiments, models 190 may have been trained using virtual substrate data 162, feature data 164, substrate data 166, etc.

Generating and utilizing virtual substrate data 162 has significant technical advantages over other methods. Developing an understanding of relationships between process operation inputs and process operation results may improve process design, product design, operation design, process operation outcomes, etc. Improving process operation outcomes may decrease costs of a process in terms of proportion of defective products produced; proportion of material, time, energy, etc., dedicated to producing defective products; performance of products; etc. By comparing predicted outcomes of a process operation to measured outcomes, deficiencies in models, processing equipment components, process recipes, or the like may be discovered, diagnosed, and corrected. Accurate correction of deficiencies may improve performance of a manufacturing system, improve predictive power of one or more models, reduce unplanned maintenance events, etc.

In some systems, metrology of substrate features may vary. For example, microscopy images of substrate features may vary in unpredictable or detrimental ways. Different images may have different characteristics, such as contrast, brightness, clarity, etc. This may be due to operator error, microscopy procedure, etc. Different features of a substrate that are designed to be identical may not be, due for instance to differences in processing conditions proximate to the locations of the features. Even identical features of a substrate may be measured or imaged differently, due for instance to instrumental limitations. Feature data 164 may be generated responsive to receiving data of a number of features. Feature data 164 may capture likely feature characteristics, average feature characteristics, target feature characteristics, or the like. Applying a process model to an array of identical features may improve reliability of input/output mappings based on the results of the process model. For example, applying a process model to an array of identical features may remove the possibility of an observed outcome being dependent on differences between features of the substrate, which may not be included in target substrate design. By varying features in a systematic way, generating several arrays of identical features, and providing the arrays of features to the process model, inferences may be drawn of the relationship between various characteristics of a feature input into a process operation and characteristics of outputs of the process operation. Parameterizing a feature (e.g., a shape of a feature, properties of a feature, etc.) may enable a robust exploration of feature property space to provide a more complete input/output mapping than may be obtained through random chance of using metrology of produced physical substrates. Parameterizing a feature may enable exploration of input feature characteristics on output results of a process operation at reduced cost compared to developing and implementing adjustments to process recipes to generate physically different features, and providing substrates with the physically different features to a process operation.

Predictive component 114 may provide current data to model 190 and may run model 190 on the input to obtain one or more outputs. For example, predictive component 114 may provide current metrology data to model 190 and may run model 190 on the input to obtain one or more outputs. Predictive component 114 may be capable of determining (e.g., extracting) predictive data 168 from the output of model 190. Predictive component 114 may determine (e.g., extract) confidence data from the output that indicates a level of confidence that predictive data 168 is an accurate predictor of a process associated with the input data for products produced or to be produced using the manufacturing equipment 124. Predictive component 114 or corrective action component 122 may use the confidence data to decide whether to cause a corrective action associated with the manufacturing equipment 124 based on predictive data 168.

The confidence data may include or indicate a level of confidence that the predictive data 168 is an accurate prediction for products or components associated with at least a portion of the input data. In one example, the level of confidence is a real number between 0 and 1 inclusive, where 0 indicates no confidence that the predictive data 168 is an accurate prediction for products processed according to input data or component health of components of manufacturing equipment 124 and 1 indicates absolute confidence that the predictive data 168 accurately predicts properties of products processed according to input data or component health of components of manufacturing equipment 124. Responsive to the confidence data indicating a level of confidence below a threshold level for a predetermined number of instances (e.g., percentage of instances, frequency of instances, total number of instances, etc.) predictive component 114 may cause trained model 190 to be re-trained (e.g., based on current sensor data 146, current manufacturing parameters, etc.). In some embodiments, retraining may include generating one or more data sets (e.g., via data set generator 172) utilizing historical data and/or synthetic data.

For purpose of illustration, rather than limitation, aspects of the disclosure describe the training of one or more machine learning models 190 using historical data, and inputting current data into the one or more trained machine learning models to determine predictive data 168. Historical data used for training may include historical metrology data, historical virtual substrate data, etc. Current data may include current metrology data, current virtual substrate data, etc. In other embodiments, a heuristic model, physics-based model, or rule-based model is used to determine predictive data 168 (e.g., without using a trained machine learning model). In some embodiments, such models may be trained using historical and/or synthetic data. In some embodiments, these models may be retrained utilizing a combination of true historical data and synthetic data. Predictive component 114 may monitor historical sensor data 144, historical manufacturing parameters, and metrology data 160. Any of the information described with respect to data inputs 210A-B of FIGS. 2A-B may be monitored or otherwise used in the heuristic, physics-based, or rule-based model.

In some embodiments, the functions of client device 120, predictive server 112, server machine 170, and server machine 180 may be provided by a fewer number of machines. For example, in some embodiments server machines 170 and 180 may be integrated into a single machine, while in some other embodiments, server machine 170, server machine 180, and predictive server 112 may be integrated into a single machine. In some embodiments, client device 120 and predictive server 112 may be integrated into a single machine. In some embodiments, functions of client device 120, predictive server 112, server machine 170, server machine 180, and data store 140 may be performed by a cloud-based service.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 may determine the corrective action based on the predictive data 168. In another example, client device 120 may determine the predictive data 168 based on output from a trained machine learning model.

In addition, the functions of a particular component can be performed by different or multiple components operating together. One or more of the predictive server 112, server machine 170, or server machine 180 may be accessed as a service provided to other systems or devices through appropriate application programming interfaces (API).

In embodiments, a “user” may be represented as a single individual. However, other embodiments of the disclosure encompass a “user” being an entity controlled by a plurality of users and/or an automated source. For example, a set of individual users federated as a group of administrators may be considered a “user.”

Embodiments of the disclosure may be applied to data quality evaluation, feature enhancement, model evaluation, Virtual Metrology (VM), Predictive Maintenance (PdM), limit optimization, process control, or the like.

FIGS. 2A-2B depict block diagrams of example data set generators 272A-B (e.g., data set generator 172 of FIG. 1) to create data sets for training, testing, validating, etc. a model (e.g., model 190 of FIG. 1), according to some embodiments. Each data set generator 272 may be part of server machine 170 of FIG. 1. In some embodiments, several machine learning models associated with manufacturing equipment 124 may be trained, used, and maintained (e.g., within a manufacturing facility). Each machine learning model may be associated with one of data set generators 272, multiple machine learning models may share a data set generator 272, etc.

FIG. 2A depicts a system 200A including data set generator 272A for creating data sets for one or more supervised models (e.g., model 190 of FIG. 1). Data set generator 272A may create data sets (e.g., data input 210A, target output 220A) using historical data and/or labelled historical data. In some embodiments, a data set generator similar to data set generator 272A may be utilized to train an unsupervised machine learning model, e.g., target output 220A may not be generated by data set generator 272A.

Data set generator 272A may generate data sets to train, test, and/or validate a model. In some embodiments, data set generator 272A may generate data sets for a machine learning model. As an example, data set generator 272A will be described in connection with a machine learning model configured to parameterize one or more characteristics of a feature. Similar data set generation may be performed for supervised machine learning models that perform other functions, with appropriate replacements in input data, target output data, etc. The machine learning model may be provided with set of feature data 264A as data input 210A. The machine learning model may be configured to accept feature measurements of one or more substrates as input and generate a parameterization of one or more characteristics of the feature as output. Parameterization may include characteristics parameterized, a standard, average, or expected set of parameter values, upper and lower parameter values, etc.

In some embodiments, data set generator 272A generates a data set (e.g., training set, validating set, testing set) that includes one or more data inputs 210A (e.g., training input, validating input, testing input). Data inputs 210A may be provided to training engine 182, validating engine 184, or testing engine 186. The data set may be used to train, validate, or test the model (e.g., model 190 of FIG. 1).

In some embodiments, data input 210A may include one or more sets of data. As an example, system 200A may produce sets of feature data that may include one or more of feature data related to one or more characteristics of the features, combinations of feature data of one or more feature characteristics, patterns from feature data from one or more measurements of characteristics of features, feature characteristics from different sets of substrates, etc.

In some embodiments, data set generator 272A may generate a first data input corresponding to a first set of feature data 264A to train, validate, or test a first machine learning model. Data set generator 272A may generate a second data input corresponding to a second set of feature data 264B (not shown) to train, validate, or test a second machine learning model. Further sets may be generated by data set generator 272A (e.g., including any number of sets of feature data to a final set, set of feature data 264Z) for training, validating, or testing further machine learning models. Any number of sets of feature data may be utilized as data input 210A, e.g., in accordance with target performance of an associated model.

In some embodiments, data set generator 272A generates a data set (e.g., training set, validating set, testing set) that includes one or more data inputs 210A (e.g., training input, validating input, testing input) and may include one or more target outputs 220A that correspond to the data inputs 210A. The data set may also include mapping data that maps the data inputs 210A to the target outputs 220A. In some embodiments, data set generator 272A may generate data for training a machine learning model configured to output feature parameterizations. Data inputs 210A may also be referred to as “features,” “attributes,” “information,” or “vectors” in some contexts. In some embodiments, data set generator 272A may provide the data set to training engine 182, validating engine 184, or testing engine 186, where the data set is used to train, validate, or test the machine learning model (e.g., one of the machine learning models that are included in model 190, ensemble model 190, etc.).

System 200B containing data set generator 272B (e.g., data set generator 172 of FIG. 1) creates data sets for one or more unsupervised machine learning models (e.g., model 190 of FIG. 1). Data set generator 272B may create data sets (e.g., data input 210B) using historical data. Data set generator 272B, as described, is configured to generate data sets for a machine learning model configured to take as input data of a set of substrates provided to a process model and a corresponding set of substrates output by the process model, and generate as output an indication of relevant or effective input/output mappings. Data set generator 272B may be associated with a machine learning model that provides a list of input features characteristics with the strongest effect on output characteristics, a set of characteristic parameters associated with generating a target output substrate, or the like. An analogous data set generator to data set generator 272B may be utilized for any unsupervised machine learning model, with corresponding substitutions of data input. Data set generator 272B may share one or more functions with data set generator 272A.

Data set generator 272B may generate data sets to train, test, and validate a machine learning model. The machine learning model is provided with set process model data 262A (e.g., input and output of a process model based on a substrate comprising an array of features) as data input 210B. The machine learning model may include two or more separate models (e.g., the machine learning model may be an ensemble model). The machine learning model may be configured to generate output data indicating impactful input substrate feature parameters, combinations of input substrate feature parameters likely to enable a target output, etc. In some embodiments, training may not include providing target output to the machine learning model. Data set generator 272B may generate data sets to train an unsupervised machine learning model.

In some embodiments, data set generator 272B generates a data set (e.g., training set, validating set, testing set) that includes one or more data inputs 210B (e.g., training input, validating input, testing input). Data inputs 210B may also be referred to as “features,” “attributes,” or “information.” In some embodiments, data set generator 272B may provide the data set to the training engine 182, validating engine 184, or testing engine 186, where the data set is used to train, validate, or test the machine learning model (e.g., model 190 of FIG. 1). Some operations of generating a training set are further described with respect to FIG. 4A.

In some embodiments, data set generator 272B may generate a first data input corresponding to a first set of process model data 262A to train, validate, or test a first machine learning model and the data set generator 272B may generate a second data input corresponding to a second set of process model data 262B to train, validate, or test a second machine learning model. Further sets of data may be generated by data set generator 272B (e.g., any target number of data sets up to a final set of process model data 262Z) for training, validating, or testing further machine learning models. Any number of sets of process model data may be utilized as data input 210A, in accordance with target performance of an associated model.

Data inputs 210B to train, validate, or test a machine learning model may include information for a particular manufacturing chamber (e.g., for particular substrate manufacturing equipment). In some embodiments, data inputs 210B may include information for a specific type of manufacturing equipment, e.g., manufacturing equipment sharing specific characteristics. Data inputs 210B may include data associated with a device of a certain type, e.g., intended function, design, produced with a particular recipe, etc. Training a machine learning model based on a type of equipment, device, recipe, etc. may allow the trained model to generate plausible predictive data in a number of settings (e.g., for a number of different facilities, products, etc.).

In some embodiments, subsequent to generating a data set and training, validating, or testing a machine learning model using the data set, the model may be further trained, validated, or tested, or adjusted (e.g., adjusting weights or parameters associated with input data of the model, such as connection weights in a neural network).

FIG. 3 is a block diagram illustrating system 300 for generating output data (e.g., predictive data 168 of FIG. 1), according to some embodiments. In some embodiments, system 300 may be used in conjunction with a machine learning model. Several functions related to generating standard features, parameterizing features, generating arrays of features, utilizing output of a process model, and/or performing corrective actions may be performed by machine learning models. In some embodiments, system 300 may be used in conjunction with a machine learning model to determine a corrective action associated with manufacturing equipment. In some embodiments, system 300 may be used in conjunction with a machine learning model to determine a fault of manufacturing equipment. In some embodiments, system 300 may be used in conjunction with a machine learning model to cluster or classify process operation results. System 300 may be used in conjunction with a machine learning model with a different function than those listed, associated with a manufacturing system. System 300 is described as being used in conjunction with a model configured to parameterize a feature of a substrate. Other models with different functions may be utilized with system 300 or an appropriate analogue.

At block 310, system 300 (e.g., components of predictive system 110 of FIG. 1) performs data partitioning (e.g., via data set generator 172 of server machine 170 of FIG. 1) of data to be used in training, validating, and/or testing a machine learning model. In some embodiments, feature data 364 includes historical data, such as historical metrology data, measurements extracted from microscopy images of historical substrates, etc. Feature data may further include associated parameterizations, e.g., parameterizations of historical features performed by subject matter experts. Feature data 364 may undergo data partitioning at block 310 to generate training set 302, validation set 304, and testing set 306. For example, the training set may be 60% of the training data, the validation set may be 20% of the training data, and the testing set may be 20% of the training data.

The generation of training set 302, validation set 304, and testing set 306 may be tailored for a particular application. For example, the training set may be 60% of the training data, the validation set may be 20% of the training data, and the testing set may be 20% of the training data. System 300 may generate a plurality of sets of attributes for each of the training set, the validation set, and the testing set. For example, if feature data 364 includes 20 measures of characteristics of one or more features, the feature data may be divided into a first set of attributes including measures 1-10 and a second set of attributes including measure 11-20. The target output data (e.g., the parameterizations) may also be divided into sets. Training input, target output, both, or neither may be divided into sets. Multiple models may be trained on different sets of data.

At block 312, system 300 performs model training (e.g., via training engine 182 of FIG. 1) using training set 302. Training of a machine learning model and/or of a physics-based model (e.g., a digital twin) may be achieved in a supervised learning manner, which involves providing a training dataset including labeled inputs through the model, observing its outputs, defining an error (by measuring the difference between the outputs and the label values), and using techniques such as deep gradient descent and backpropagation to tune the weights of the model such that the error is minimized. In many applications, repeating this process across the many labeled inputs in the training dataset yields a model that can produce correct output when presented with inputs that are different than the ones present in the training dataset. In some embodiments, training of a machine learning model may be achieved in an unsupervised manner, e.g., labels or classifications may not be supplied during training. An unsupervised model may be configured to perform anomaly detection, result clustering, etc.

For each training data item in the training dataset, the training data item may be input into the model (e.g., into the machine learning model). The model may then process the input training data item (e.g., a number of measured dimensions of a manufactured device, a cartoon picture of a manufactured device, etc.) to generate an output. The output may include, for example, a parameterization of a feature of a substrate. The output may be compared to a label of the training data item (e.g., an effective parameterization of the feature generated by another method).

Processing logic may then compare the generated output (e.g., parameterization) to the label (e.g., provided target parameterization) that was included in the training data item. Processing logic determines an error (i.e., a classification error) based on the differences between the output and the label(s). Processing logic adjusts one or more weights and/or values of the model based on the error.

In the case of training a neural network, an error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

System 300 may train multiple models using multiple sets of attributes of the training set 302 (e.g., a first set of attributers of the training set 302, a second set of attributes of the training set 302, etc.). For example, system 300 may train a model to generate a first trained model using the first set of attributes in the training set (e.g., feature measurements 1-10, measurements from substrates 1-10, measurements from one or more locations of multiple substrates, etc.) and to generate a second trained model using the second set of attributes in the training set (e.g., feature measurements 11-20, etc.). In some embodiments, the first trained model and the second trained model may be combined to generate a third trained model (e.g., which may be a better predictor or synthetic data generator than the first or the second trained model on its own). In some embodiments, sets of attributes used in comparing models may overlap (e.g., first set of attributes being from feature measurements 1-15 and second set of attributes being from feature measurements 5-20). In some embodiments, hundreds of models may be generated including models with various permutations of attributes and combinations of models.

At block 314, system 300 performs model validation (e.g., via validation engine 184 of FIG. 1) using the validation set 304. The system 300 may validate each of the trained models using a corresponding set of features of the validation set 304. For example, system 300 may validate the first trained model using the first set of attributes in the validation set (e.g., metrology measurements 1-10) and the second trained model using the second set of attributes in the validation set (e.g., metrology measurements 11-20). In some embodiments, system 300 may validate hundreds of models (e.g., models with various permutations of features, combinations of models, etc.) generated at block 312. At block 314, system 300 may determine an accuracy of each of the one or more trained models (e.g., via model validation) and may determine whether one or more of the trained models has an accuracy that meets a threshold accuracy. Responsive to determining that none of the trained models has an accuracy that meets a threshold accuracy, flow returns to block 312 where the system 300 performs model training using different sets of attributes of the training set. Responsive to determining that one or more of the trained models has an accuracy that meets a threshold accuracy, flow continues to block 316. System 300 may discard the trained models that have an accuracy that is below the threshold accuracy (e.g., based on the validation set).

At block 316, system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow may return to block 312 where the system 300 performs model training using further refined training sets corresponding to further refined sets of attributes for determining a trained model that has the highest accuracy.

At block 318, system 300 performs model testing (e.g., via testing engine 186 of FIG. 1) using testing set 306 to test selected model 308. System 300 may test, using the first set of attributes in the testing set (e.g., sensor data from sensors 1-10), the first trained model to determine the first trained model meets a threshold accuracy (e.g., based on the first set of attributes of the testing set 306). Responsive to accuracy of the selected model 308 not meeting the threshold accuracy (e.g., the selected model 308 is overly fit to the training set 302 and/or validation set 304 and is not applicable to other data sets such as the testing set 306), flow continues to block 312 where system 300 performs model training (e.g., retraining) using different training sets corresponding to different sets of attributes (e.g., different feature measurements). Responsive to determining that selected model 308 has an accuracy that meets a threshold accuracy based on testing set 306, flow continues to block 320. In at least block 312, the model may learn patterns in the training data to make predictions or generate feature parameterizations, and in block 318, the system 300 may apply the model on the remaining data (e.g., testing set 306) to test the predictions or parameterization generation.

At block 320, system 300 uses the trained model (e.g., selected model 308) to receive current data 322 (e.g., current metrology data, such as measurements from a substrate the recipe of which is undergoing optimization) and determines (e.g., extracts), from the output of the trained model, feature parameterization 324. A corrective action associated with the manufacturing equipment 124 of FIG. 1 may be performed in view of feature parameterization 324. For example, based on feature parameterization 324, a number of features may be generated that differ in value of one or more parameter values from a central or standard feature. A multi-dimensional grid of features may be generated, where each dimension of the grid corresponds to a parameter, and each position on the dimension corresponds to a value of the corresponding parameter within a range (e.g., the range may be included in feature parameterization 324). In some embodiments, current data 322 may correspond to the same types of attributes in the historical data used to train the machine learning model. In some embodiments, current data 322 corresponds to a subset of the types of attributes in historical data that are used to train selected model 308 (e.g., a machine learning model may be trained using a number of metrology measurements, and configured to generate output based on a subset of metrology measurements).

In some embodiments, the performance of a machine learning model trained, validated, and tested by system 300 may deteriorate. For example, a manufacturing system associated with the trained machine learning model may undergo a gradual change or a sudden change. A design for a substrate to be provided to a process operation in question may change. Details of the process operation may change, or a corresponding process model may change. Such a change in the manufacturing system may result in decreased performance of the trained machine learning model. A new model may be generated to replace the machine learning model with decreased performance. The new model may be generated by altering the old model by retraining, by generating a new model, etc. Retraining of a model may be performed by providing additional training data, including training input data and target output data. Retraining of a model may be performed by providing updated feature data 346 as additional training data. Updated feature data 346 may include data associated with an updated processing system, such as updated substrate design, updated process recipe, updated process equipment, updated process model, or the like.

In some embodiments, one or more of the acts 310-320 may occur in various orders and/or with other acts not presented and described herein. In some embodiments, one or more of acts 310-320 may not be performed. For example, in some embodiments, one or more of data partitioning of block 310, model validation of block 314, model selection of block 316, or model testing of block 318 may not be performed.

FIG. 3 depicts a system configured for training, validating, testing, and using one or more machine learning models. The machine learning models are configured to accept data as input (e.g., set points provided to manufacturing equipment, sensor data, metrology data, etc.) and provide data as output (e.g., predictive data, corrective action data, classification data, etc.). Partitioning, training, validating, selection, testing, and using blocks of system 300 may be executed similarly to train a second model, utilizing different types of data. Retraining may also be done, utilizing current data 322 and/or updated feature data 346.

FIGS. 4A-D are flow diagrams of methods 400A-D associated with utilizing feature measurements to generate input/output mappings for a process operation for performing corrective actions, according to some embodiments. Methods 400A-D may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, methods 400A-D may be performed, in part, by predictive system 110. Method 400A may be performed, in part, by predictive system 110 (e.g., server machine 170 and data set generator 172 of FIG. 1, data set generators 272A-B of FIGS. 2A-2B). Predictive system 110 may use method 400A to generate a data set to at least one of train, validate, or test a machine learning model, in accordance with embodiments of the disclosure. Methods 400B-D may be performed by predictive server 112 (e.g., predictive component 114) and/or server machine 180 (e.g., training, validating, and testing operations may be performed by server machine 180). In some embodiments, a non-transitory machine-readable storage medium stores instructions that when executed by a processing device (e.g., of predictive system 110, of server machine 180, of predictive server 112, etc.) cause the processing device to perform one or more of methods 400A-D.

For simplicity of explanation, methods 400A-D are depicted and described as a series of operations. However, operations in accordance with this disclosure can occur in various orders and/or concurrently and with other operations not presented and described herein. Furthermore, not all illustrated operations may be performed to implement methods 400A-D in accordance with the disclosed subject matter. In addition, those skilled in the art will understand and appreciate that methods 400A-D could alternatively be represented as a series of interrelated states via a state diagram or events.

FIG. 4A is a flow diagram of a method 400A for generating a data set for a machine learning model, according to some embodiments. Referring to FIG. 4A, in some embodiments, at block 401 the processing logic implementing method 400A initializes a training set T to an empty set.

At block 402, processing logic generates first data input (e.g., first training input, first validating input) that may include one or more of sensor, manufacturing parameters, metrology data, etc. In some embodiments, the first data input may include a first set of attributes for types of data and a second data input may include a second set of attributes for types of data (e.g., as described with respect to FIG. 3). Input data may include historical data and/or synthetic data in some embodiments. Input data may include feature data, feature parameter data, process model input and output data, etc.

In some embodiments, at block 403, processing logic optionally generates a first target output for one or more of the data inputs (e.g., first data input). In some embodiments, the input includes one or more metrology measurements and the target output is a parameterization of a substrate feature. In some embodiments, the first target output is predictive data. In some embodiments, no target output is generated (e.g., an unsupervised machine learning model capable of grouping or finding correlations in input data, rather than having target output provided).

At block 404, processing logic optionally generates mapping data that is indicative of an input/output mapping. The input/output mapping (or mapping data) may refer to the data input (e.g., one or more of the data inputs described herein), the target output for the data input, and an association between the data input(s) and the target output. In some embodiments, such as in association with machine learning models where no target output is provided, block 404 may not be executed.

At block 405, processing logic adds the mapping data generated at block 404 to data set T, in some embodiments.

At block 406, processing logic branches based on whether data set T is sufficient for at least one of training, validating, and/or testing a machine learning model, such as model 190 of FIG. 1. If so, execution proceeds to block 407, otherwise, execution continues back at block 402. It should be noted that in some embodiments, the sufficiency of data set T may be determined based simply on the number of inputs, mapped in some embodiments to outputs, in the data set, while in some other embodiments, the sufficiency of data set T may be determined based on one or more other criteria (e.g., a measure of diversity of the data examples, accuracy, etc.) in addition to, or instead of, the number of inputs.

At block 407, processing logic provides data set T (e.g., to server machine 180) to train, validate, and/or test a machine learning model, such as machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210A) are input to the neural network, and output values (e.g., numerical values associated with target outputs 220A) of the input/output mapping are stored in the output nodes of the neural network. The connection weights in the neural network are then adjusted in accordance with a learning algorithm (e.g., back propagation, etc.), and the procedure is repeated for the other input/output mappings in data set T. After block 407, a model (e.g., model 190) can be at least one of trained using training engine 182 of server machine 180, validated using validating engine 184 of server machine 180, or tested using testing engine 186 of server machine 180. The trained model may be implemented by predictive component 114 (of predictive server 112) to generate predictive data 168 for performing signal processing, to generate synthetic data 162, or for performing a corrective action associated with manufacturing equipment 124.

FIG. 4B is a flow diagram of a method 400B for utilizing measurements of features of a substrate for performing a corrective action, according to some embodiments. At block 410, processing logic receives profile data of a plurality of features of a substrate. A profile of a feature may be a shape, one or more characteristics, data points along a border, a function describing a boundary, or the like. The plurality of features may be of a substrate. The plurality of features may further include features of multiple substrates. The plurality of features may be nominally identical, e.g., may be designed for similar geometry, properties, performance, etc. The plurality of features may further be of multiple substrates that are nominally identical, e.g., that may have been produced using the same process recipe, the same process equipment, the same type of equipment, designed to perform the same function, etc.

Profile data of the plurality of features may be extracted from one or more microscopy images. The microscopy images may be of one or more substrates. The microscopy images may be of one or more features, may be of portions of features, may include profiles of features, etc. The microscopy images may be TEM images, SEM images, XSEM images, or images generated by other imaging techniques. Data describing one or more profiles of features may be extracted from the images, e.g., by a model such as a machine learning model.

At block 412, processing logic generates a typical profile based on the profile data of the plurality of features. The typical profile may be a profile of a typical feature. The typical profile and/or typical feature may be generated by taking an average, median, mode, or some other metric of one or more characteristics of the features and/or profiles under consideration (e.g., the plurality of features). The typical profile may be a profile of a measured feature, e.g., a feature with measurements best approximating a median or average of the measured features.

Generating a typical profile may include generating a parameterization of a feature and/or feature profile. A parameterization may describe characteristics of the feature with a number of adjustable parameters. For example, slopes, distances, radii of curvature, etc., may be generated as parameters to describe a feature, a feature profile, etc. Generating a parameterization may be performed manually. Generating a parameterization may be performed by a model. Generating a parameterization may be performed by a machine learning model. Generating a parameterization may include considering statistics of provided profile data, e.g., a range of radii of curvature of a characteristic of the plurality of features. Generating a parameter may include generating a typical value and/or generating a range of values of the parameter. A typical profile or typical feature may include any combination of parameter values within the generated ranges. Generating and utilizing parameterization of a feature will be discussed in more detail in connection with FIG. 4C.

At block 414, processing logic generates a first array of features, wherein each of the first array of features is based on the typical profile. The first array of features may comprise a virtual or synthetic substrate. The virtual substrate may include data indicative of properties of a substrate. The virtual substrate may comprise an array of identical features, e.g., an array of features having the typical profile. The first array of features may be a two dimensional array. The first array of features may be a three dimensional array. The virtual substrate may comprise a two dimensional or three dimensional array of features. The virtual substrate may comprise an array of feature arranged in a line (e.g., the features may include properties in two dimensions, parallel and perpendicular to the arrangement of the array). The virtual substrate may comprise an array of features arranged in a grid (e.g., the features may include properties in three dimensions, parallel and perpendicular to the two-dimensional grid or array of features).

At block 416, processing logic provides the first array of features to a process model. The process model predicts the results of applying one or more process operations to an input substrate. The input substrate may include the first array of features. The output may be a prediction of properties of the output substrate of a physical substrate processing procedure given the input substrate. The process model may be a physics-based model. The process model may be a deposition model. The process model may be an etch model. The process model may be configured to predict the results of any process operations or combination of process operations.

At block 418, processing logic obtains first output from the process model based on the first array of features. The output may include data indicative of predicted properties of a substrate after undergoing further processing, after undergoing one or more further process operations, etc. Output of the process model may be indicative of one or more effects that input feature profile to a process operation has on output of the process operation. In some embodiments, multiple arrays of features may be provided to the process model. The multiple arrays may each comprise somewhat different features, e.g., features with different profiles, features with different values of parameters, or the like. Output received by the processing logic may include input/output mapping data, e.g., a collection of data indicating effects of input to the process model on output from the process model. Modeling a set of arrays of features will be discussed in more detail in connection with FIG. 4D.

At block 419, processing logic causes performance of a corrective action in view of the first output from the process model. The corrective action may include an update. The update may be an update in design of an input product to a process operation, an update of a process recipe, etc. The corrective action may include maintenance, such as corrective or preventative maintenance. The corrective action may include providing an alert to a user. The alert may include notifying a user of a recommended update to a process operation. The alert may include notifying a user of a recommended update to a product design. The alert may include notifying a user of an effect that a property of an input substrate has on one or more properties of an output substrate of a process operation.

FIG. 4C is a flow diagram of a method 400C for generating and utilizing parameterization of a feature, according to some embodiments. At block 420, processing logic receives profile data of a plurality of features. The features may be of one or more substrates. The profile data may include data indicative of one or more shapes, boundaries, or regions occupied by the features. The profile data may be extracted from microscopy images of the features. The profile data may be extracted from microscopy images of features as input to a target process operation (e.g., measurements of a substrate may be taken before the substrate is provided to a target process operation). The profile data may be extracted from measurements taken after the target process operation is performed (e.g., properties of the input substrate may be extrapolated from measurements of the output substrate of a process operations, e.g., by XSEM).

At block 422, processing logic generates a parametric representation of a typical profile based on the profile data. In some embodiments, generation of a parametric representation may instead be performed manually. Generation of a parametric representation may be performed by a machine learning model. The parametric representation may include abstract parameters, e.g., coefficients of a fit of the profile of a feature. The parametric representation may include physical parameters, e.g., rounding radii, slopes, distances, etc., of a parameterized feature. Characteristics that are parameterized may be selected based on a range of inputs to the parameterization process. For example, a rounding radius may not be selected for parameterization from a set of features, responsive to the set of features (or set of feature profiles) having little variation in the rounding radius.

At block 424, a parameter value of the typical profile is altered to generate a second profile. For example, a rounding radius or slope may be altered compared to the typical profile to generate a new profile, a new feature, etc.

At block 426, a first and second array of features are generated. The first and second arrays of features may comprise a first and second substrate. The first array of features may each be identical to a typical feature, e.g., each of the first array of features may share the typical profile. The first substrate may comprise the first array of features, each comprising the typical profile. The second array of features may each be identical to a second feature, e.g., each of the second array of features may comprise the second profile. The second substrate may comprise the second array of features, each comprising the second profile.

At block 428, the first array of features (e.g., the first substrate) and the second array of features (e.g., the second substrate) are provided to a process model. The process model may predict the results of performing a process operation. For example, the process model may predict the results of performing a deposition or etch operation on substrates corresponding to the first and second substrates.

In some embodiments, a first virtual substrate provided to a process model may include an array of identical features. A second virtual substrate provided to the process model may include a second array of identical features, wherein the second array is different from the first. Each feature of the second array may be different from each feature of the first array. The arrangement of features of the second array may be different from the arrangement of features of the first array. Many more virtual substrates may be generated and provided to the process model. Many virtual substrates, beyond the first and second, may be generated that are different from the first and second substrates. Each of the virtual substrates may include an array of features. Each array of features may be different than the other arrays of features. Each array of features may include features of a shape, profile, properties, arrangement, or the like different from the other arrays of features. All features of a single substrate may be identical. In some embodiments, the effect of differently shaped features on a single substrate may be of interest, and a virtual substrate may include features with different shapes, profiles, properties, etc.

At block 429, processing logic receives output from the process model based on the first and second arrays of features. Output of the process model may be predicted results of a process operation performed on a physical substrate. Output of the process model may include input/output mappings, e.g., output of the process model may include an indication of an effect on output that the alteration of the parameter value of the typical profile has. Output of the process model may be utilized in performing a corrective action, e.g., may be utilizing in updating substrate design, process operations recipes, or the like. In some embodiments, more arrays of features may be generated and provided to the process model. A multi-dimensional grid of profiles may be generated, each differing in value of one or more parameter from the typical profile. Exploration of input substrate property space to a process operation may be explored in this way, input/output mappings spanning a portion of input property space and output property space may be analyzed, etc.

FIG. 4D is a flow diagram of a method 400D for obtaining predictive output from a process model, according to some embodiments. At block 430, Processing logic generates a first set of profiles. Each of the first set of profiles differs in a value of at least one parameters from a parametric representation of a typical profile. Operations of block 430 may optionally include additional operations, represented in blocks 432-436.

At block 432, processing logic optionally generates a second set of profiles. Each of the second set of profiles is generated by adjusting one or more parameter values from values of the parametric representation of the typical profile. Each of the second set of profiles is unique, e.g., each of the second set is different from all others of the second set. The second set of profiles may include a thorough exploration of the parameterization of the profile. For example, the second set of profiles may include combinations of parameters spanning from a lower parameter value limit to an upper parameter value limit of each parameter. In some embodiments, a series of values within range may be generated for each parameter. The second set of profiles may include profiles which have each combination of each of the series of values for each parameter. The second set of profiles may include fewer profiles, e.g., some combinations of parameter values may be excluded.

At block 434, processing logic provides the second set of profiles to a trained machine learning model. At block 436, processing logic obtains from the trained machine learning model output. The output includes the first set of profiles, e.g., the first set of profiles is a subset of the second set of profiles. The trained machine learning model is configured to determine one or more of the second set of profiles which are not to be used to generate an array of features. The trained machine learning model may be configured to exclude combinations of parameter values that are unphysical, unlikely to occur, overly expensive to generate (e.g., expensive in terms of cost, time, energy, material, reliability, etc., exceeding a threshold), or the like. The trained machine learning model may be a supervised model, e.g., it may have been trained with labelled training data. The trained machine learning model may have been provided with training data labelled manually. The trained machine learning model may have been provided with training data separated into categories, such as physically probable structures and physically improbable structures. The trained machine learning model may be an unsupervised model, e.g., it may be provided with training data that is not labeled, and be configured to exclude parameter value combinations that are not within the parameter space spanned by the training data.

At block 438, processing logic generates a set of arrays of features, each array associated with one of the first set of profiles. Each array may be an array of identical features. Each feature of an array of features may include the corresponding profile. Each of the arrays of features may be or comprise a virtual substrate. At block 440, processing logic provides each of the set of arrays of features to a process model.

At block 442, processing logic obtains from the process model a set of outputs. Each of the set of outputs are associated with one of the set of arrays of features. The output may be predicted outcomes of providing a substrate including an array of features to a process operation.

At block 444, processing logic optionally provides the first set of profiles and the set of outputs to a trained machine learning model. The trained machine learning model may be configured to generate one or more indications of the effect of input to the process model (e.g., details of a profile of a feature) on output from the model (e.g., performance of the process operation associated with the process model). The trained machine learning model may be configured to extract a number of impactful input parameters. The trained machine learning model may be configured to list input parameters with the most significant impact on output properties. The trained machine learning model may be configured to generate input/output mappings, such as a multidimensional fit.

At block 446, processing logic obtains from the trained machine learning model one or more indications of mappings between profile parameters and process model outputs. One or more corrective actions may be performed in view of the output from the trained machine learning model.

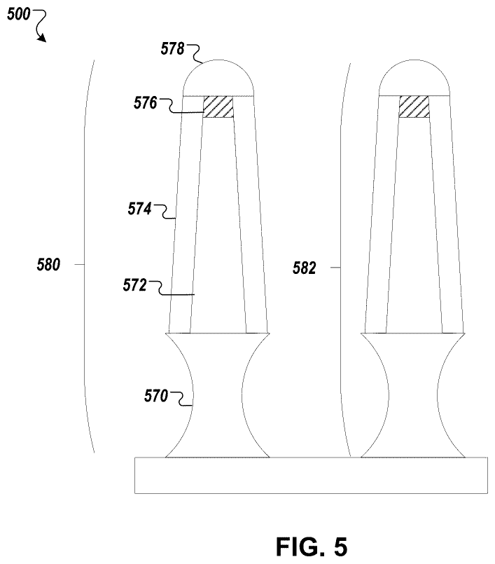

FIG. 5 depicts an example substrate 500 including features, according to some embodiments. Substrate 500 may be a physical substrate. Substrate 500 may be a virtual substrate. The substrate 500 may be similar to a microscopy image of a device, e.g., an XSEM or TEM image. Aspects of the present disclosure include providing data indicative of properties of a substrate to a process model that corresponds to one or more process operations. Substrate 500 may be a substrate that has not yet undergone the corresponding process operations. Substrate 500 may be a substrate that has undergone the corresponding process operations.

Substrate 500 includes a number of features. Substrate 500 includes nominally identical features 580 and 582. Device features may include multiple components, be defined by multiple characteristics, etc. Portions of feature 580 stand atop pedestal 570. The device may include a feature with a gate 572. The gate may be surrounded by spacers 574, and topped by mask 576. Deposition material 578 may be disposed on top of mask 576. Other devices, other designs, etc., are within the scope of this disclosure.

The process model may be an etch model, a deposition model, or another model configured to predict results of one or more process operations. For example, the process model may predict outcomes of a process operation that results in deposition of deposition material 578. Measurements of features 580 and 582 may be performed before deposition of deposition material 578 or after deposition of deposition material 578. Some measurement techniques, such as XSEM, may be capable of measuring properties and/or profiles of features that existed before a process operation was performed. For example, an XSEM metrology system may provide data from which the shape of feature 580 before deposition may be extracted and provided to a process model.

Characteristics of a feature may include radii of curvature, slope, distances, thicknesses, and other properties. For example, the radius of curvature of bowing of pedestal 570, slopes of various edges of components such as spacers 574 and/or gate 572, etc., may be characteristics of feature 580. Characteristics of feature 580 may be parameterized, e.g., based on variations between characteristics of feature 580 and feature 582, based on variations between characteristics of feature 580 and other features of substrate 500, based on variations between characteristics of feature 580 and other features of other substrates, etc.

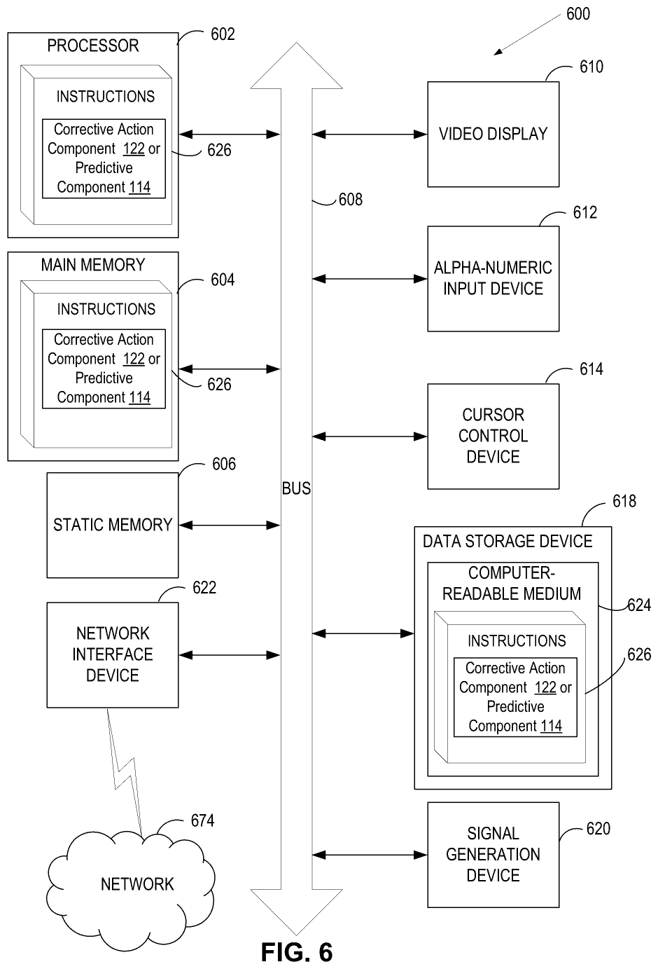

FIG. 6 is a block diagram illustrating a computer system 600, according to some embodiments. In some embodiments, computer system 600 may be connected (e.g., via a network, such as a Local Area Network (LAN), an intranet, an extranet, or the Internet) to other computer systems. Computer system 600 may operate in the capacity of a server or a client computer in a client-server environment, or as a peer computer in a peer-to-peer or distributed network environment. Computer system 600 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 600 may include a processing device 602, a volatile memory 604 (e.g., Random Access Memory (RAM)), a non-volatile memory 606 (e.g., Read-Only Memory (ROM) or Electrically-Erasable Programmable ROM (EEPROM)), and a data storage device 618, which may communicate with each other via a bus 608.

Processing device 602 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 600 may further include a network interface device 622 (e.g., coupled to network 674). Computer system 600 also may include a video display unit 610 (e.g., an LCD), an alphanumeric input device 612 (e.g., a keyboard), a cursor control device 614 (e.g., a mouse), and a signal generation device 620.

In some embodiments, data storage device 618 may include a non-transitory computer-readable storage medium 624 (e.g., non-transitory machine-readable medium) on which may store instructions 626 encoding any one or more of the methods or functions described herein, including instructions encoding components of FIG. 1 (e.g., predictive component 114, corrective action component 122, model 190, etc.) and for implementing methods described herein.

Instructions 626 may also reside, completely or partially, within volatile memory 604 and/or within processing device 602 during execution thereof by computer system 600, hence, volatile memory 604 and processing device 602 may also constitute machine-readable storage media.

While computer-readable storage medium 624 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “altering,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and embodiments, it will be recognized that the present disclosure is not limited to the examples and embodiments described. The scope of the disclosure should be determined with reference to the following claims, along with the full scope of equivalents to which the claims are entitled.

1. A method, comprising:
receiving profile data of a plurality of features of a substrate;
generating a typical profile based on the profile data of the plurality of features;
generating a first array of features, wherein each of the first array of features is based on the typical profile;
providing the first array of features to a process model;
obtaining first output from the process model based on the first array of features; and
causing performance of a corrective action in view of the first output from the process model.

2. The method of claim 1, further comprising:
receiving a microscopy image comprising the plurality of features of the substrate; and
extracting the profile data of the plurality of features from the microscopy image.

3. The method of claim 1, wherein generating the typical profile comprises:
representing the profile data of the plurality of features as a plurality of sets of characteristic parameters; and
performing a statistical analysis to generate a set of characteristic parameters comprising the typical profile.

4. The method of claim 1, wherein each feature of the first array of features comprises the typical profile.

5. The method of claim 1, further comprising:
generating a parametric representation of the typical profile;
altering a parameter of the typical profile to generate a second profile;
generating a second array of features, wherein each of the second array of features is based on the second profile;
providing the second array of features to the process model; and
obtaining second output from the process model based on the second array of features, wherein causing performance of the corrective action is in further view of the second output from the process model.

6. The method of claim 5, wherein generating the parametric representation comprises providing the profile data of the plurality of features to a trained machine learning model, and obtaining as output from the trained machine learning model parameters of the parametric representation.

7. The method of claim 5, further comprising:
generating a first set of profiles, wherein each of the first set of profiles differs in a value of at least one parameter from the parametric representation of the typical profile;
generating a set of arrays of features, each array associated with one of the first set of profiles;
proving each of the set of arrays of features to the process model; and
obtaining from the process model a set of outputs, each of the set of outputs associated with one of the set of arrays of features.

8. The method of claim 7, wherein generating the first set of profiles comprises:
generating a second set of profiles, wherein each of the second set of profiles is generated by adjusting one or more parameter values associated with the parametric representation of the typical profile;
providing the second set of profiles to a trained machine learning model; and
obtaining from the trained machine learning model the first set of profiles, wherein the trained machine learning model is to determine one or more of the second set of profiles which are not to be used to generate an array of features.

9. The method of claim 7, further comprising:
providing the first set of profiles to a trained machine learning model;
providing the set of outputs to the trained machine learning model; and
obtaining from the trained machine learning model one or more indications of mappings between profile parameters and process model outputs.

10. The method of claim 1, wherein the corrective action comprises one or more of:
scheduling maintenance of a substrate processing system;
updating a substrate processing recipe; or
providing an alert to a user.

11. The method of claim 1, wherein the process model comprises a physics-based deposition model.

12. A system, comprising memory and a processing device coupled to the memory, wherein the processing device is to:
receive profile data of a plurality of features, wherein the features are each a feature of a substrate;
generate a typical profile based on the profile data of the plurality of features;
generate a first array of features, wherein each of the first array of features is based on the typical profile;
provide the first array of features to a process model;
obtain first output from the process model based on the first array of features; and
cause performance of a corrective action in view of the first output from the process model.

13. The system of claim 12, wherein each feature of the first array of features comprises the typical profile.

14. The system of claim 12, wherein the processing device is further to:
generate a parametric representation of the typical profile;
alter a first parameter of the typical profile to generate a second profile;
generate a second array of features, wherein each of the second array of features is based on the second profile;
provide the second array of features to the process model; and
obtain second output from the process model based on the second array of features, wherein causing performance of the corrective action is in further view of the second output from the process model.

15. The system of claim 14, wherein the processing device is further to:
generate a first set of profiles, wherein each of the first set of profiles differs in a value of at least one parameter from the parametric representation of the typical profile;
generate a set of arrays of features, each array of the set of arrays associated with one of the first set of profiles;
provide each of the set of arrays of features to the process model; and
obtain from the process model a set of outputs, each of the set of outputs associated with one of the set of arrays of features.

16. The system of claim 12, wherein the processing device is further to:
receive one or more microscopy images comprising the plurality of features; and
extract the profile data of the plurality of features from the one or more microscopy images.

17. A non-transitory machine-readable storage medium storing instructions which, when executed, cause a processing device to perform operations comprising:
receiving profile data of a plurality of features of a substrate;
generating a typical profile based on the profile data of the plurality of features;
generating a first array of features, wherein each of the first array of features is based on the typical profile;
providing the first array of features to a process model;
obtaining first output from the process model based on the first array of features; and
causing performance of a corrective action in view of the first output from the process model.

18. The non-transitory machine-readable storage medium of claim 17, wherein the operations further comprise:
generating a parametric representation of the typical profile;
altering a parameter of the typical profile to generate a second profile;
generating a second array of features, wherein each of the second array of features is based on the second profile;
providing the second array of features to the process model; and
obtaining second output from the process model based on the second array of features, wherein causing performance of the corrective action is in further view of the second output from the process model.

19. The non-transitory machine-readable storage medium of claim 18, wherein generating the parametric representation comprises providing the profile data of the plurality of features to a trained machine learning model, and obtaining as output from the trained machine learning model parameters of the parametric representation.

20. The non-transitory machine-readable storage medium of claim 18, wherein the operations further comprise:
generating a first set of profiles, wherein each of the first set of profiles differs in a value of at least one parameter from the parametric representation of the typical profile;
generating a set of arrays of features, each array associated with one of the first set of profiles;
proving each of the set of arrays of features to the process model; and
obtaining from the process model a set of outputs, each of the set of outputs associated with one of the set of arrays of features.
